(19) United States
(12) Patent Application Publication
(10) Pub. No.: US 2012/0212924 A1
(43) Pub. Date: Aug. 23, 2012

(54) ELECTRONIC APPARATUS

(75) Inventor: Yuji Nakajima, Nishitama-gun (JP)

(73) Assignee: KABUSHIKI KAISHA TOSHIBA, Tokyo (JP)

(21) Appl. No.: 13/272,095

(22) Filed: Oct. 12, 2011

(30) Foreign Application Priority Data
Feb. 18, 2011 (JP) 2011-033806

(51) Int. Cl. H05K 7/00

(52) U.S. Cl. 361/807

(57) ABSTRACT

According to one embodiment, an electronic apparatus includes a first housing, a second housing, a hinge, and a movable portion. The first housing includes an operation surface. The hinge attaches the second housing to the first housing. The movable portion is attached to an end of the first housing by the hinge and is configured to be rotated toward an opposite side to the operation surface in synchronization with rotation of the second housing.

### CROSS-REFERENCE TO RELATED APPLICATIONS

This application is based upon and claims the benefit of priority from prior Japanese Patent Application No. 2011-033806, filed Feb. 18, 2011, the entire contents of which are incorporated herein by reference.

### FIELD

Embodiments described herein relate generally to an electronic apparatus.

### BACKGROUND

An electronic apparatus has been proposed in which a display portion is rotated with respect to a main portion.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view illustrating the closed state of an electronic apparatus according to a first embodiment;

FIG. 2 is an exemplary perspective view illustrating the open state of the electronic apparatus shown in FIG. 1;

FIG. 3 is an exemplary cross-sectional view illustrating the electronic apparatus shown in FIG. 1;

FIG. 4 is an exemplary perspective view schematically illustrating the internal structure of the electronic apparatus shown in FIG. 1;

FIG. 5 is an exemplary perspective view illustrating a region surrounded by a line F5 in the electronic apparatus shown in FIG. 4;

FIG. 6 is an exemplary perspective view illustrating a region surrounded by a line F6 in the electronic apparatus shown in FIG. 4;

FIG. 7 is an exemplary perspective view illustrating a hinge shown in FIG. 5;

FIG. 8 is an exemplary exploded perspective view illustrating the hinge shown in FIG. 7;

FIG. 9 is an exemplary diagram illustrating the motion of the hinge shown in FIG. 7;

FIG. 10 is an exemplary diagram illustrating a first modification of the electronic apparatus shown in FIG. 1;

FIG. 11 is an exemplary perspective view illustrating a second modification of the electronic apparatus shown in FIG. 1;

FIG. 12 is an exemplary perspective view illustrating a third modification of the electronic apparatus shown in FIG. 1;

FIG. 13 is an exemplary perspective view illustrating a fourth modification of the electronic apparatus shown in FIG. 1;

FIG. 14 is an exemplary perspective view illustrating another state of the hinge shown in FIG. 13;

FIG. 15 is an exemplary cross-sectional view illustrating a fifth modification of the electronic apparatus shown in FIG. 1;

FIG. 16 is an exemplary perspective view illustrating a sixth modification of the electronic apparatus shown in FIG. 1;

FIG. 17 is an exemplary perspective view illustrating the closed state of an electronic apparatus according to a second embodiment;

FIG. 18 is an exemplary perspective view illustrating the open state of the electronic apparatus shown in FIG. 17; and

FIG. 19 is an exemplary perspective view illustrating an electronic apparatus according to a third embodiment.

### DETAILED DESCRIPTION

Various embodiments will be described hereinafter with reference to the accompanying drawings.

In general, according to one embodiment, an electronic apparatus comprises a first housing, a second housing, a hinge, and a movable portion. The first housing comprises an operation surface. The hinge attaches the second housing to the first housing. The movable portion is attached to an end of the first housing by the hinge and is configured to be rotated toward an opposite side to the operation surface in synchronization with rotation of a second housing.

Hereinafter, exemplary embodiments will be described with reference to the accompanying drawings.

### First Embodiment

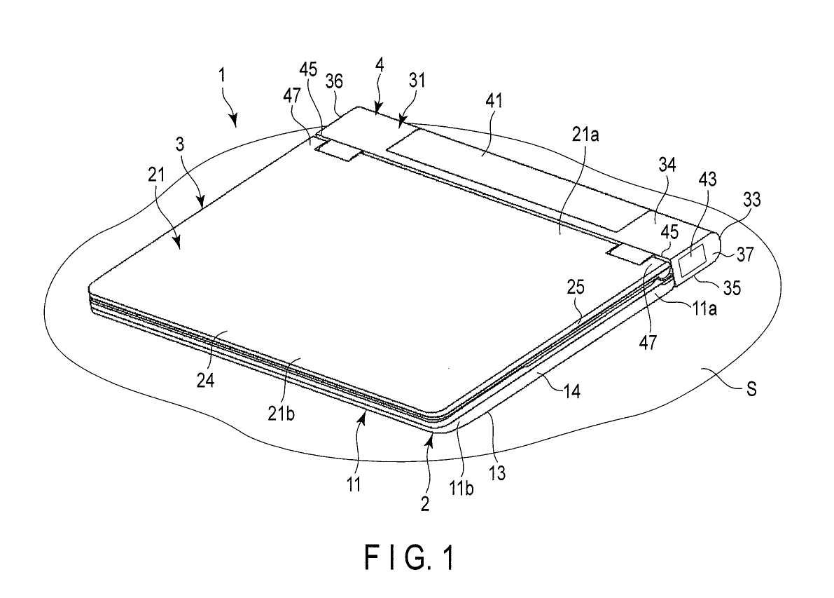

FIGS. 1 to 16 show an electronic apparatus 1 according to a first embodiment. The electronic apparatus 1 is, for example, a notebook personal computer (notebook PC). The electronic apparatus to which this embodiment can be applied is not limited to the above. This embodiment can be widely applied to various kinds of electronic apparatuses including, for example, a mobile phone, a smart phone, an electronic book terminal, a personal digital assistant (PDA), and a game machine.

As shown in FIGS. 1 to 4, the electronic apparatus 1 includes a first unit 2 (for example, a main portion), a second unit 3 (for example, a display portion), a third unit 4 (for example, a tilt portion), and hinges 5 and 6. The first unit 2 includes a first housing 11. The first housing 11 includes an upper wall 12, a lower wall 13, and a circumferential wall 14 and has a flat box shape. The upper wall 12 is an example of a “first wall.” The lower wall 13 is an example of a “second wall” and is disposed opposite to the upper wall 12.

The lower wall 13 faces a desk surface S (mounting surface) when the electronic apparatus 1 is placed on a desk. The lower wall 13 is provided with, for example, a plurality of legs 15. When the electronic apparatus 1 is folded and placed on the desk, the legs 15 touch the desk surface S and support the electronic apparatus 1.

The upper wall 12 is opposite to the lower wall 13 with a gap therebetween and extends substantially in parallel to the lower wall 13. A keyboard 16 is attached to the upper wall 12. The keyboard 16 is an example of an “input portion” (input receiving portion). As the input portion, another input mechanism, such as a touch panel, may be used. The upper wall 12 on which the input portion, such as the keyboard 16, is provided is an example of an “operation surface” that receives an input to the electronic apparatus 1. For convenience of explanation, in some cases, the “upper wall 12” is referred to as the “operation surface 12.”

The circumferential wall 14 rises with respect to the lower wall 13, and connects the edge portion of the lower wall 13 and the edge portion of the upper wall 12. A circuit board 17 is provided in the first housing 11. An example of the circuit board 17 is a main board. The circuit board 17 may be provided in a second housing 21 which will be described below.

The first housing 11 includes a first end portion 11a (for example, a rear end portion) and a second end portion 11b (for example, a front end portion). The hinges 5 and 6 are connected to the first end portion 11a. The second end portion 11b is disposed opposite to the first end portion 11a. In the specification, the side close to the user of the electronic apparatus 1 is defined as a “front side” and the side away from the user is defined as a “rear side.” In addition, the left and right sides are defined on the basis of the viewing direction of the user of the electronic apparatus 1.

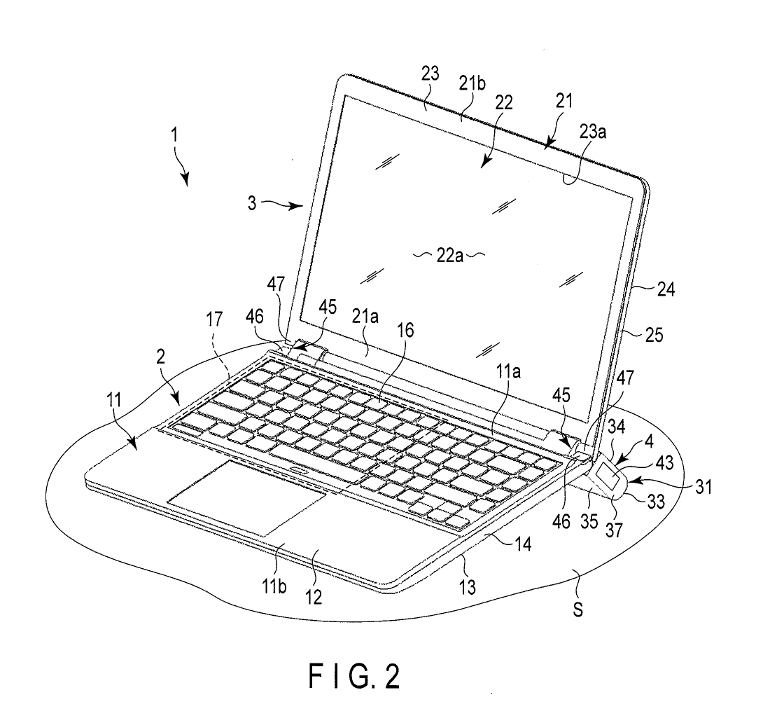

As shown in FIG. 2, the second unit 3 includes the second housing 21 and a display device 22 accommodated in the second housing 21. The display device 22 is, for example, a liquid crystal display, but is not limited thereto. The display device 22 includes a display screen 22a on which an image or a video is displayed.

The second housing 21 is rotatably (openably) connected to the first end portion 11a of the first housing 11 by the hinges 5 and 6. The second housing 21 can be rotated between a first position (first posture) where the second housing 21 overlaps the first housing 11 and covers the first housing 11 and a second position (second posture) where the second housing 21 is rotated from the first position in a direction in which it is separated from the operation surface 12 such that the operation surface 12 is exposed to the outside.

The second housing 21 includes a front wall 23, a rear wall 24, and a circumferential wall 25 and has a flat box shape. When the second housing 21 is disposed at the first position, the front wall 23 faces the operation surface 12 of the first housing 11. The front wall 23 includes an opening portion 23a through which the display screen 22a of the display device 22 is exposed. The rear wall 24 is opposite to the front wall 23 with a gap therebetween and extends substantially in parallel to the front wall 23. The circumferential wall 25 rises with respect to the front wall 23 and the rear wall 24, and connects the edge portion of the front wall 23 and the edge portion of the rear wall 24.

The second housing 21 includes a first end portion 21a (for example, a lower end portion) and a second end portion 21b (for example, an upper end portion). The hinges 5 and 6 are connected to the first end portion 21a. The second end portion 21b is disposed opposite to the first end portion 21a. In the specification, each portion is defined on the basis of the posture of the electronic apparatus 1 at the second position.

The third unit 4 includes a third housing 31. The third housing 31 is an example of a “movable portion.” As shown in FIG. 1, the third housing 31 is provided on the rear side of the first housing 11 and the second housing 21. When the first housing 11 and the second housing 21 overlap each other, the third housing 31 is provided at a position where it does not overlap the first housing 11 and the second housing 21.

The third housing 31 is thicker than the first housing 11 and the second housing 21. The thickness of the third housing 31 is substantially equal to, for example, the sum of the thickness of the first housing 11 and the thickness of the second housing 21. When the first housing 11 overlaps the second housing 21, the surface (for example, the upper surface) of the third housing 31 and the surface (for example, the upper surface) of the second housing 21 are positioned substantially on the same plane.

The thickness of the third housing 31 may be less or more than the sum of the thickness of the first housing 11 and the thickness of the second housing 21. When the thickness of the third housing 31 is substantially equal to or less than the sum of the thickness of the first housing 11 and the thickness of the second housing 21, the portability of the electronic apparatus 1 is improved.

As shown in FIG. 1, the third housing 31 is positioned close to (for example, in the vicinity of) the first end portion 11a of the first housing 11 and the first end portion 21a of the second housing 21 and is adjacent to the first end portion 11a of the first housing 11 and the first end portion 21a of the second housing 21. The third housing 31 extends in the longitudinal direction of the first housing 11. The length (width) of the third housing 31 is substantially equal to width of each of the first housing 11 and the second housing 21.

When the first housing 11 and the second housing 21 overlap each other, the third housing 31 is substantially parallel to the first housing 11 and the second housing 21 and extends substantially in parallel to the first housing 11 and the second housing 21. That is, in the lateral direction (a direction from the second end portion 11b to the first end portion 11a) of the first housing 11, the first housing 11 and the third housing 31 are connected substantially in a straight line.

As shown in FIGS. 1 to 3, the third housing 31 includes a front wall 32, a rear wall 33, an upper wall 34, a lower wall 35, a left wall 36, and a right wall 37. When the first housing 11 and the second housing 21 overlap each other, the front wall 32 extends substantially in the vertical direction and faces the first housing 11 and the second housing 21. The rear wall 33 is disposed opposite to the front wall 32.

When the first housing 11 and the second housing 21 overlap each other, the upper wall 34 extends substantially in parallel to the rear wall 24 of the second housing 21 and is disposed substantially on the same plane as that on which the rear wall 24 extends. When the first housing 11 and the second housing 21 overlap each other, the lower wall 35 extends substantially in parallel to the lower wall 13 of the first housing 11 and is disposed substantially on the same plane as that on which the lower wall 13 extends. The left wall 36 and the right wall 37 are provided at the left and right ends of the third housing 31 and connect the edge portion of the front wall 32 and the edge portion of the rear wall 33.

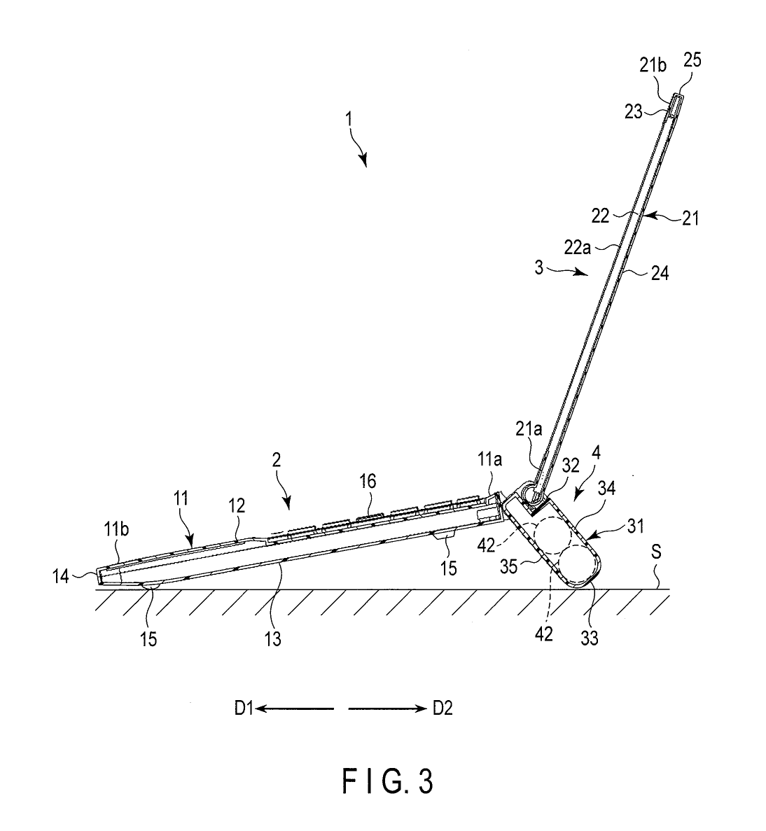

As shown in FIGS. 1 and 3, a battery 41 is provided in the third housing 31. For example, the battery 41 is thicker than the first housing 11, and is thicker the second housing 21. The battery 41 is one of the heavy components of the electronic apparatus 1 and is heavier than, for example, the circuit board 17. Since the third housing 31 includes the battery 41, it is relatively heavy. As shown in FIG. 3, the battery 41 includes a cylindrical cell 42 (battery cell). At least a portion of the rear wall 33 of the third housing 31 has, for example, an arc shape along the outward shape of the cell 42.

As shown in FIG. 1, a connector 43 is mounted on the left wall 36 or the right wall 37 of the third housing 31. The connector 43 is an example of an “electronic component” and is provided in the third housing 31. The electronic component provided in the third housing 31 is not limited to the connector. For example, power supply components related to the battery 41 or other components may be provided in the third housing 31. An example of the connector 43 is an LAN connector, such as RJ45, or an RGB connector, which is a large connector with a relatively large height. The connector 43 is exposed to the outside.

As shown in FIGS. 2 and 3, at least a portion of the third housing 31 is disposed between the first housing 11 and the second housing 21. A pair of receiving portions 45 is provided at the left and right leading ends of the third housing 31. The receiving portion 45 is recessed to the inside of the third housing 31. The first housing 11 includes a pair of protruding portions 46 that protrudes toward the receiving portions 45 of the third housing 31. The second housing 21 includes a pair of protruding portions 47 that protrudes toward the receiving portions 45 of the third housing 31.

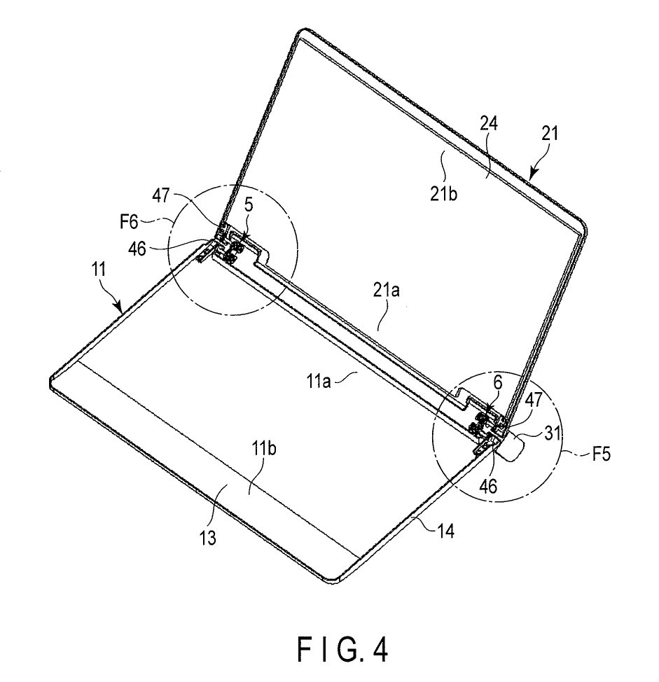

As shown in FIGS. 4 to 6, a pair of hinges 5 and 6 is provided at the left and right ends of the electronic apparatus 1, respectively and connects the first housing 11, the second housing 21, and the third housing 31 such that they can be rotated. The hinge 5 provided at the left end of the electronic apparatus 1 has substantially the same structure and function as the hinge 6 provided at the right end. Therefore, the hinge 6 provided at the right end will be described in detail below as a representative. In the hinge 6, components having the same functions as those in the hinge 5 provided at the left end are denoted by the same reference numerals and a description thereof will not be repeated.

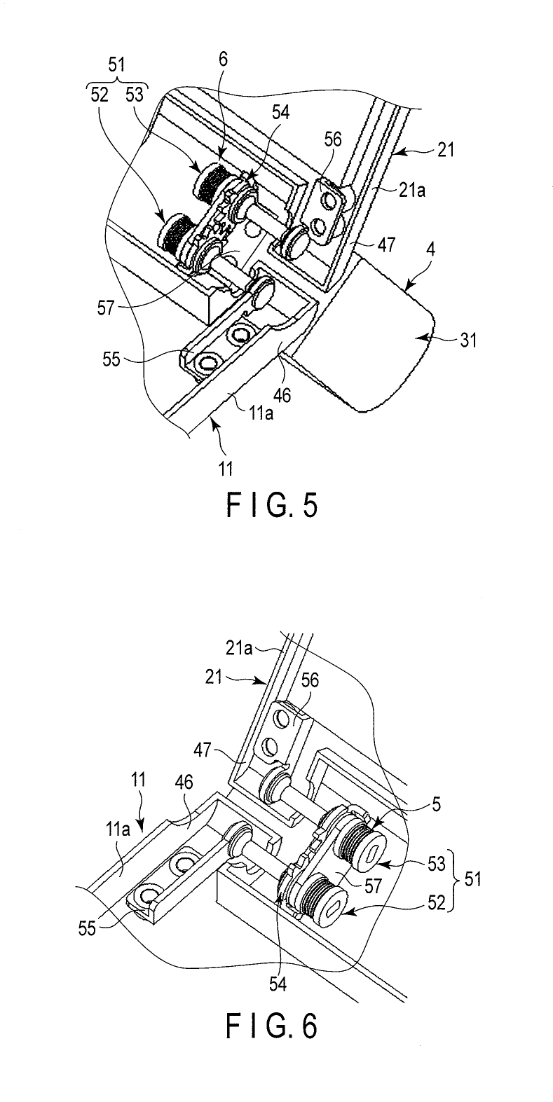

As shown in FIG. 5 and FIGS. 7 to 9, the hinge 6 includes a biaxial hinge mechanism 51. The biaxial hinge mechanism 51 includes a first hinge 52, a second hinge 53, and an interlock 54. The first hinge 52 is provided between the first housing 11 and the third housing 31 and connects the first housing 11 and the third housing 31 such that the first and third housings can be rotated. The second hinge 53 is provided between the second housing 21 and the third housing 31 and connects the second housing 21 and the third housing 31 such that the second and third housings can be rotated. The interlock 54 operatively associates the motion of the first hinge 52 with the motion of the second hinge 53.

Specifically, the biaxial hinge mechanism 51 includes a first fixed portion 55 (for example, a main portion fixed metal member) fixed to the first housing 11, a second fixed portion 56 (for example, a display portion fixed metal member) fixed to the second housing 21, and a third fixed portion 57 (for example, a tilt portion fixed metal member) fixed to the third housing 31. The first fixed portion 55 is a portion of the first hinge 52. The second fixed portion 56 is a portion of the second hinge 53. The third fixed portion 57 is a portion of the first hinge 52 and is also a portion of the second hinge 53. The third fixed portion 57 is a hinge holder that supports hinge shafts of the first and second hinges 52 and 53 and includes two holes 57a and 57b (supporting holes).

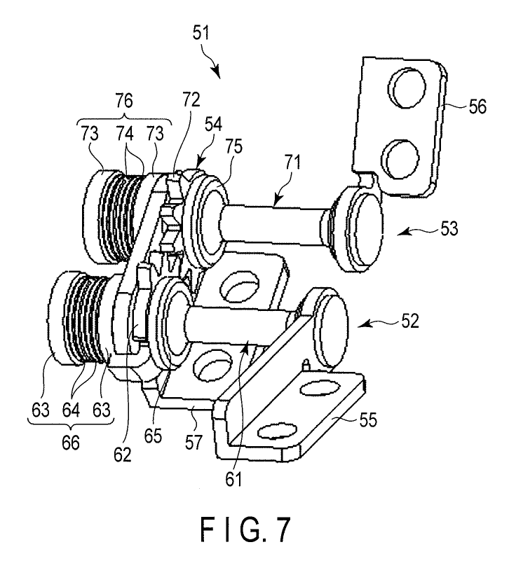

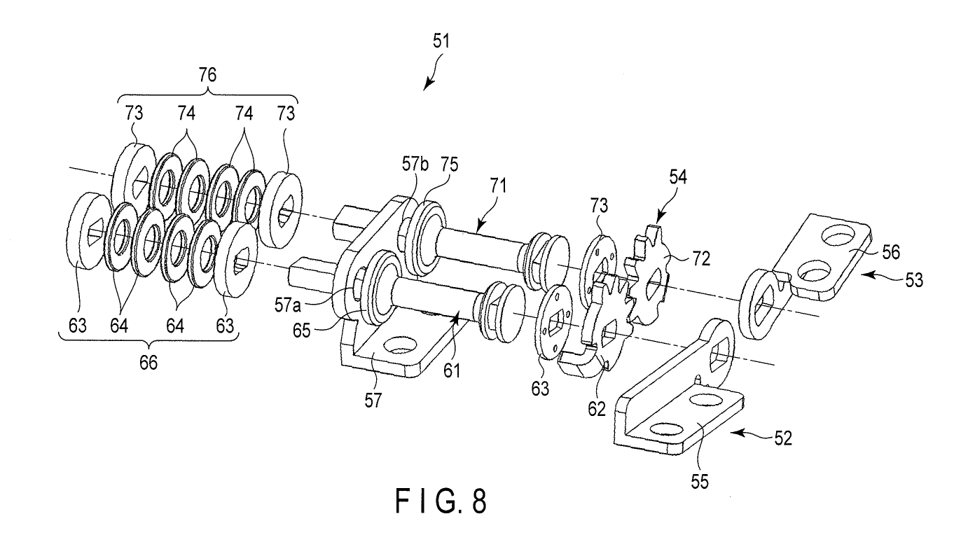

As shown in FIGS. 7 and 8, the first hinge 52 includes a first shaft 61 (first hinge shaft), a first gear 62, washers 63, and disc springs 64. The first fixed portion 55 is provided to the end of the first shaft 61. The first shaft 61 is inserted into the hole 57a of the third fixed portion 57 and is rotatably supported by the third fixed portion 57. The first shaft 61 includes a large-diameter portion 65 having a side facing the third fixed portion 57.

The first gear 62 is provided between the third fixed portion 57 and the large-diameter portion 65 of the first shaft 61 and is fixed to the first shaft 61. The first gear 62 is disposed coaxially with the first shaft 61. The washers 63 and the disc springs 64 are attached to the first shaft 61 and provide a first brake portion 66 that gives torque (brake torque) to the first hinge 52.

The first brake portion 66 comes into contact with the third fixed portion 57 from the opposite side of the large-diameter portion 65 of the first shaft 61 and presses the third fixed portion 57 against the first gear 62. In this way, predetermined torque is applied between the third fixed portion 57 and the first shaft 61.

Similarly, the second hinge 53 includes a second shaft 71 (second hinge shaft), a second gear 72, washers 73, and disc springs 74. The second fixed portion 56 is provided to the end of the second shaft 71. The second shaft 71 is inserted into the hole 57b of the third fixed portion 57 and is rotatably supported by the third fixed portion 57. The second shaft 71 includes a large-diameter portion 75 having a side facing the third fixed portion 57.

The second gear 72 is provided between the third fixed portion 57 and the large-diameter portion 75 of the second shaft 71 and is fixed to the second shaft 71. The second gear 72 is disposed coaxially with the second shaft 71. The washers 74 and the disc springs 74 are attached to the second shaft 71 and provide a second brake portion 76 that gives torque (brake torque) to the second hinge 53.

The second brake portion 76 comes into contact with the third fixed portion 57 from the opposite side of the large-diameter portion 75 of the second shaft 71 and presses the third fixed portion 57 against the second gear 72. In this way, predetermined torque is applied between the third fixed portion 57 and the second shaft 71.

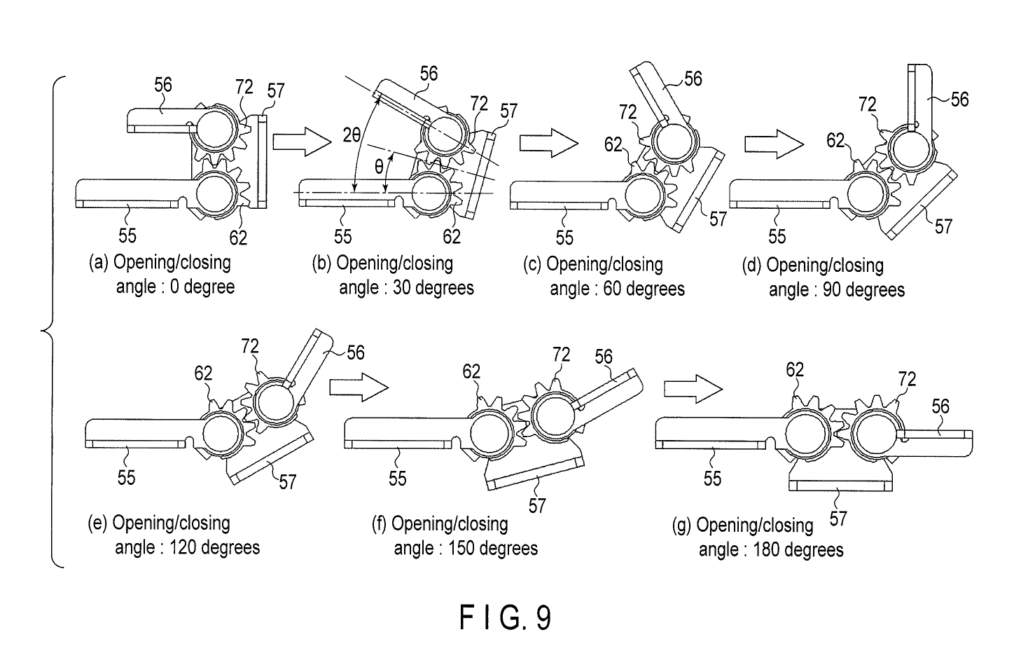

The second gear 72 is engaged with the first gear 62. That is, the first and second gears 62 and 72 are operatively associated with (i.e., synchronized with) each other. The first and second gears 62 and 72 provide an example of the interlock 54. In this way, as shown in FIG. 9, the first hinge 52 and the second hinge 53 are operatively associated with each other. When the second fixed portion 56 is rotated with respect to the first fixed portion 55, the third fixed portion 57 is also rotated with respect to the first fixed portion 55. That is, when the second housing 21 is rotated with respect to the first housing 11, the third housing 31 is automatically rotated with respect to the first housing 11.

Specifically, as shown in FIGS. 2 and 3, the third housing 31 is connected to the first end portion 11a of the first housing 11 and the first end portion 21a of the second housing 21 by the hinges 5 and 6. When the first housing 11 and the second housing 21 are opened, that is, when the second housing 21 is rotated in a direction away from the operation surface 12 of the first housing 11, the electronic apparatus 1 is in a used state in which the operation surface 12 and the display screen 22a are exposed to the outside.

In this case, the third housing 31 is automatically rotated to the side opposite to the operation surface 12 in operative association with (i.e., synchronized with) the rotation of the second housing 21. That is, when the second housing 21 is rotated in the direction away from the operation surface 12, the third housing 31 is automatically rotated such that the third housing 31 protrudes to the side opposite from the operation surface 12.

In other words, when the electronic apparatus 1 is used, the third housing 31 is changed from a position where it is parallel to the first housing 11 to a position where it is rotated about the shaft 61 of the first hinge 52 and is inclined with respect to the first housing 11. In this way, the third housing 31 protrudes downward from the leg 15 provided at the rear end portion of the lower wall 13 of the first housing 11.

As such, when the third housing 31 protrudes on the opposite side of the operation surface 12, the first end portion 11a of the first housing 11 is lifted by the third housing 31 and is higher than the second end portion 11b. The second end portion 11b of the first housing 11 and the third housing 31 come into contact with the desk surface S, and the first housing 11 is supported by the second end portion 11b of the first housing 11 and the third housing 31. In this case, the first end portion 11a of the first housing 11 is lifted from the desk surface S.

As shown in FIG. 3, when the electronic apparatus 1 is used, the first housing 11 is inclined such that the first end portion 11a is higher than the second end portion 11b in a first direction D1. That is, the first housing 11 is inclined downward toward the front side. The third housing 31 is inclined downward in a second direction D2 opposite to the first direction D1. That is, the third housing 31 is inclined downward toward the rear side.

As shown in FIG. 3, when the electronic apparatus 1 is used, the second end portion 11b of the first housing 11 and the third housing 31 are disposed separately front side and rear side of the hinges 5 and 6. The first housing 11 is supported in different directions by the second end portion 11b of the first housing 11 and the third housing 31.

As shown in FIG. 9, the gear ratio of the first gear 62 to the second gear 72 is, for example, 1:1. That is, the first and second gears 62 and 72 include rotating bodies having the same diameter and teeth with the same size. Therefore, when the rotation angle between the first fixed portion 55 and the second fixed portion 56 is 2θ, the rotation angle between the first fixed portion 55 and the third fixed portion 57 is θ. That is, when the second housing 21 is rotated with respect to the first housing 11, the rotation angle of the third housing 31 with respect to the first housing 11 is half the rotation angle between the first housing 11 and the second housing 21.

In other words, the amount of rotation of the second housing 21 is the sum of the amount of rotation of the first hinge 52 and the amount of rotation of the second hinge 53, and the amount of rotation of the third housing 31 is equal to the amount of rotation of the first hinge 52. In this way, the rotation angle of the third housing 31 with respect to the first housing 11 is smaller than the rotation angle of the second housing 21 with respect to the first housing 11. The “amount of rotation of the first hinge” means the amount of rotation of the third fixed portion 57 with respect to the first fixed portion 55. The “amount of rotation of the second hinge” means the amount of rotation of the second fixed portion 56 with respect to the third fixed portion 57.

Next, the operation of the electronic apparatus 1 will be described.

As shown in FIG. 1, when the electronic apparatus 1 is not used, the second housing 21 overlaps the first housing 11 so as to cover the operation surface 12. In this case, in the electronic apparatus 1, the first housing 11 and the third housing 31 are aligned in a straight line. Therefore, the electronic apparatus 1 has a good storage property and high portability.

As shown in FIGS. 2 and 3, when the electronic apparatus 1 is used, the user holds, for example, the second end portion 21b of the second housing 21 and rotates the second housing 21 in a direction away from the operation surface 12. In this way, the operation surface 12 and the display screen 22a are exposed to the outside such that the user can operate the electronic apparatus 1.

In this case, the third housing 31 is automatically rotated with the rotation of the second housing 21 and inclined downward. In this way, the first end portion 11a of the first housing 11 is lifted up and the first housing 11 is inclined upward toward the rear side. Therefore, the input portion (for example, the keyboard 16) provided in the first housing 11 is also inclined upward toward the rear side.

According to this structure, it is possible to provide an electronic apparatus that has a small thickness and is inclined in use.

The thickness of the electronic apparatus, such as a notebook PC, has been reduced in order to improve portability. However, when the thickness of the electronic apparatus 1 is reduced, it is difficult to form an angle between the input portion, such as a keyboard, and the desk surface and wrist strain is likely to occur when the keyboard is used to input information.

For comparison, a certain electronic apparatus is considered. The following structure is considered in which slide legs provided in the housing slide to the outside in order to incline the electronic apparatus in use. In an A4-size (width: 210 mm) notebook PC, for example, in order to obtain a tilt angle of 5 degrees, the rear end portion of the electronic apparatus needs to be lifted up by about 18 mm. The slide leg protrudes from the housing by 18 mm in order to stably support the electronic apparatus. In this case, the slide leg needs to be in the inside of the housing by substantially the same distance as that from the housing to the outside in order to stably support the electronic apparatus.

Therefore, the slide leg needs to have a total length of at least 36 mm. In addition, the thickness of the housing or the thickness of a portion to which the hinge is fixed is added to the thickness of the electronic apparatus. Therefore, the thickness of the housing is likely to be more than 40 mm. For example, in order to obtain a tilt angle of 10 degrees, the thickness of the housing further increases.

The slide leg is likely to wobble. This is because a given clearance (backlash) between the slide leg and a receiving portion that receives the slide leg is needed in order to slide the slide leg from the housing. Therefore, it is difficult to stably hold the slide leg and the notebook PC is likely to wobble in use.

In contrast, in this embodiment, the electronic apparatus 1 includes the first housing 11 including the operation surface 12, the second housing 21, the hinges 5 and 6, and the movable portion 31 that is connected to the end portion of the first housing 11 and is rotated to the opposite side of the operation surface 12 in operative association with the rotation of the second housing 21. In this structure, when the second housing 21 is rotated, the movable portion 31 is automatically rotated and protrudes downward from the first housing 11. In this way, the first housing 11 is inclined upward toward the rear side and the operation surface 12 provided in the first housing 11 is also inclined upward toward the rear side. Therefore, wrist strain is less likely to occur when the user inputs information with the keyboard.

The movable portion 31 is rotated, for example, from a substantially parallel position and protrudes from the opposite side of the operation surface 12. According to this structure, it is possible to reduce the thickness of the first housing 11, as compared to the structure including the slide legs. In addition, in the rotating structure, a necessary clearance is less than that in the sliding structure of the slide legs and the rotating structure is less likely to wobble than the sliding structure. Therefore, the electronic apparatus 1 is stabilized in use.

In this embodiment, the electronic apparatus 1 includes the first hinge 52 that connects the first housing 11 and the third housing 31 so as to be rotatable, the second hinge 53 that connects the second housing 21 and the third housing 31 so as to be rotatable, and the interlock 54 that operatively associates the first hinge 52 with the second hinge 53. According to this structure, it is possible to reduce the size of the hinges 5 and 6 that rotate the third housing 31 in operative association with the rotation of the second housing 21. This contributes to reducing the thickness of the electronic apparatus 1.

In this embodiment, when the electronic apparatus 1 is used, the first housing 11 is inclined downward toward the front side and the third housing 31 is inclined downward toward the rear side. Therefore, the first housing 11 is supported in a plurality of different directions by the second end portion 11b and the third housing 31. Therefore, the first housing 11 is stably supported and it is possible to stably use the electronic apparatus 1.

In this embodiment, an electronic component (for example, the connector 43) is provided in the third housing 31. That is, an electronic component is provided in a tilt portion that inclines the electronic apparatus 1. This structure contributes to increasing mounting density in the electronic apparatus 1 and reducing the thickness of the electronic apparatus 1.

In this embodiment, the battery 41, which is a relatively heavy component of the electronic apparatus 1, is provided in the third housing 31. Therefore, even when the first end portion 11a of the first housing 11 is lifted up, the center of gravity of the electronic apparatus 1 is likely to be maintained at a low position and the electronic apparatus 1 is likely to be stabilized.

The battery 41 is one of the relatively thick components of the electronic apparatus 1. When the battery 41 is provided in the third housing 31, the battery 41 does not overlap the display device 22, which makes it possible to design an electronic apparatus with a small thickness. In this way, it is possible to provide the electronic apparatus 1 with high portability. When the battery 41 is provided in the third housing 31, it is possible to reduce the thickness of the first and second housings 11 and 21, regardless of the thickness of the battery 41 and thus reduce the thickness of the electronic apparatus 1.

In this embodiment, when the electronic apparatus 1 is not used, the third housing 31 is provided at a position where it does not overlap the first housing 11 and the second housing 21 and is thicker than the first housing 11. The connector 43 is provided in the third housing 31 with a relatively large thickness. Therefore, it is possible to reduce the thickness of the first housing 11, regardless of the height (thickness) of the connector 43, and thus reduce the thickness of the electronic apparatus 1.

In this embodiment, the thickness of the third housing 31 is substantially equal to the sum of the thickness of the first housing 11 and the thickness of the second housing 21. When the second housing 21 overlaps the first housing 11, the surface of the third housing 31 and the surface of the second housing 21 are disposed substantially on the same plane. According to this structure, the portability and outward appearance of the electronic apparatus 1 are improved.

In this embodiment, when the electronic apparatus 1 is not used, the third housing 31 is substantially parallel to the first housing 11. That is, when the electronic apparatus 1 is not used, it is flat. According to this structure, when the electronic apparatus 1 is not used, the thickness of the electronic apparatus 1 is reduced. Therefore, the storage property or portability of the electronic apparatus 1 is improved.

In this embodiment, the amount of rotation of the second housing 21 is equal to the sum of the amount of rotation of the first hinge 52 and the amount of rotation of the second hinge 53, and the amount of rotation of the third housing 31 is equal to the amount of rotation of the first hinge 52. The rotation angle of the third housing 31 is less than that of the second housing 21. According to this structure, it is possible to rotate the third housing 31 by an angle required for tilting.

In this embodiment, the rear wall 33 of the third housing 31 has an arc shape. The rear wall 33 is a wall portion that comes into contact with the desk surface S when the electronic apparatus 1 is used. When the rear wall 33 has an arc shape, the third housing 31 is likely to stably come into contact with the desk surface S, regardless of the rotation angle of the third housing 31. Therefore, the electronic apparatus 1 is stably supported.

Next, some modifications of the electronic apparatus 1 will be described. Structures other than the following structures are the same as those in the above-described embodiment.

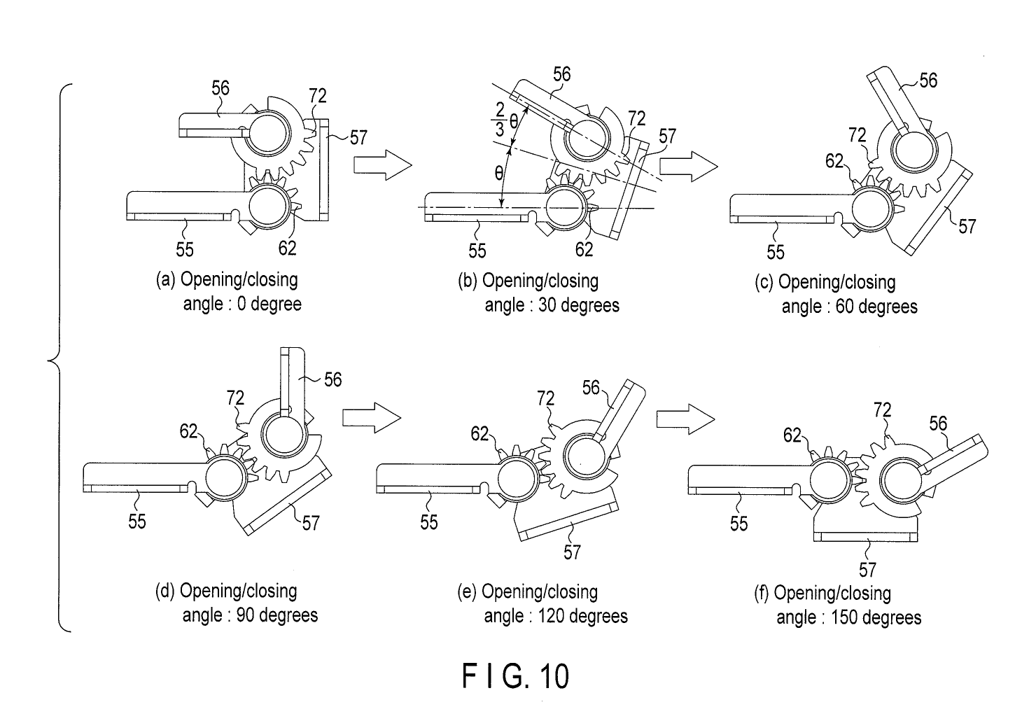

FIG. 10 shows a first modification of the electronic apparatus 1. As shown in FIG. 10, the gear ratio of the first gear 62 to the second gear 72 is not limited to 1:1. In this modification, the gear ratio of the first gear 62 to the second gear 72 is, for example, 2:3. Therefore, when the rotation angle between the first fixed portion 55 and the third fixed portion 57 is θ, the rotation angle between the third fixed portion 57 and the second fixed portion 56 is 2θ/3.

Therefore, in this modification, when the second housing 21 is rotated by the same angle, the rotation angle of the third housing 31 is more than that in the case in which the gear ratio is 1:1. Therefore, it is possible to increase the inclination angle of the first housing 11. That is, it is possible to provide the electronic apparatus 1 with a large tilt angle.

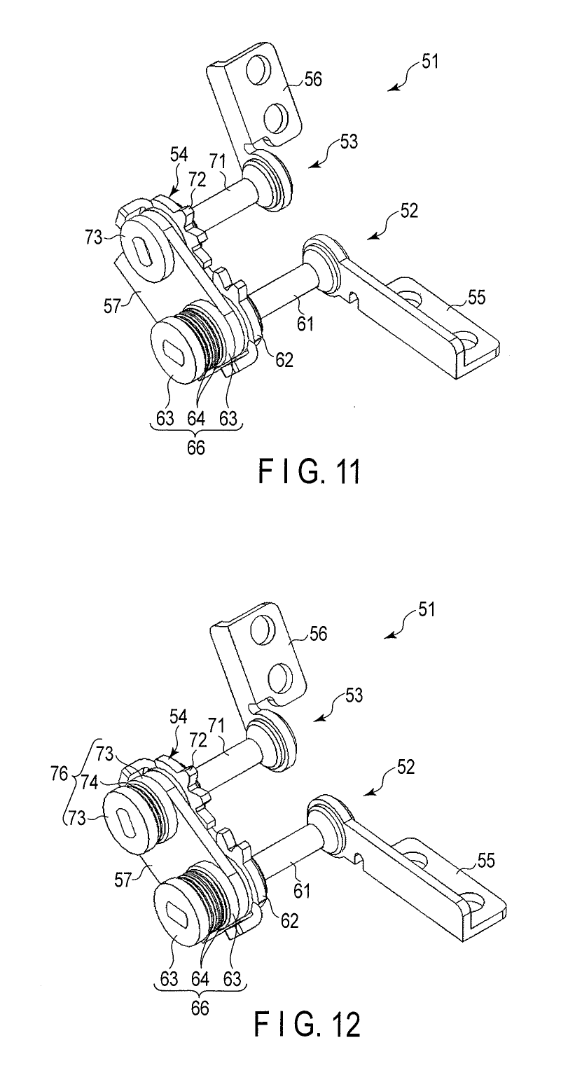

FIG. 11 shows a second modification of the electronic apparatus 1. As shown in FIG. 11, in this modification, the brake portion 76 of the second hinge 53 is not provided. Even when the brake portion 76 of the second hinge 53 is not provided, the second hinge 53 can receive torque from the first brake portion 66 through the first and second gears 62 and 72. The brake portion including the disc springs is relatively expensive. Therefore, the structure with which the brake portion 76 is not provided contributes to reducing the costs of the electronic apparatus 1. Instead of omitting the brake portion 76 of the second hinge 53, the brake portion 66 of the first hinge 52 may be omitted.

FIG. 12 shows a third modification of the electronic apparatus 1. As shown in FIG. 12, in this modification, the number of the disc springs of the brake portion 76 of the second hinge 53 is less than that of the disc springs in the above-described embodiment, and torque is reduced. According to this structure, it is possible to reduce the costs of the electronic apparatus 1 and it is possible to improve the effect of suppressing the second hinge 53 from wobbling, as compared to, for example, the second modification.

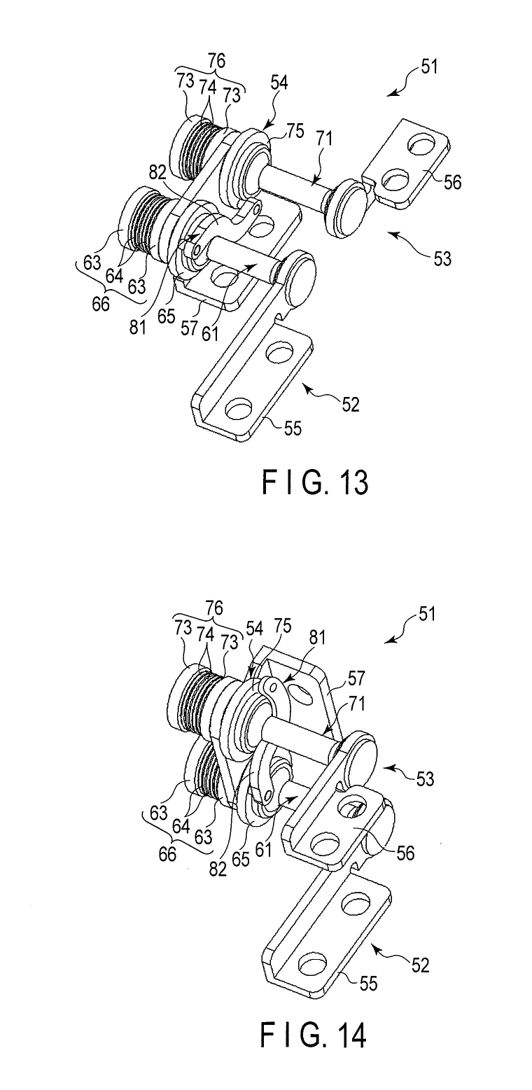

FIGS. 13 and 14 show a fourth modification of the electronic apparatus 1. As shown in FIG. 13, the interlock 54 according to this modification includes a link mechanism 81 that operatively associates the motion of the first hinge 52 with the motion of the second hinge 53, instead of the first and second gears 62 and 72.

The link mechanism 81 includes a link piece 82. A first end portion of the link piece 82 is rotatably connected to, for example, the large-diameter portion 65 of the first shaft 61 of the first hinge 52. A second end portion of the link piece 82 is rotatably connected to, for example, the large-diameter portion 75 of the second shaft 71 of the second hinge 53. The first and second hinges 52 and 53 are operatively associated with (i.e., synchronized with) each other through the link piece 82.

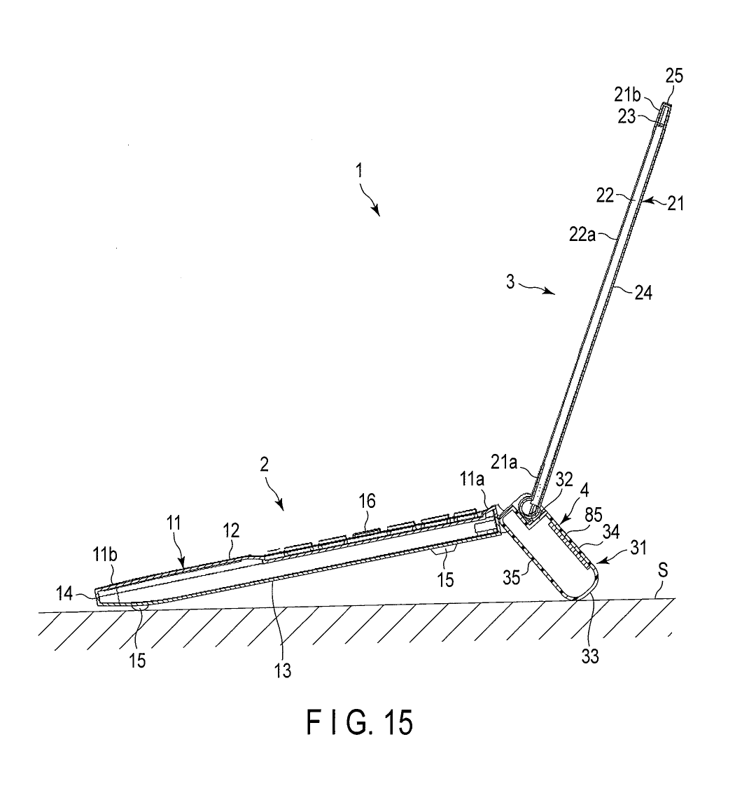

FIG. 15 shows a fifth modification of the electronic apparatus 1. As shown in FIG. 15, in this modification, an antenna 85 is provided in the third housing 31. The antenna 85 is an example of the “electronic component.” The first and second housings 11 and 21 are made of metal, for example. The third housing 31 is made of plastic. The antenna 85 is arranged along, for example, the upper wall 34 of the third housing 31. When the electronic apparatus 1 is in use, the antenna 85 faces in a direction different from the directions in which the first and second housings 11 and 21 exist and is not covered with the first and second housings 11 and 21. According to this structure, the transmission and reception of signals by the antenna are less likely to be affected by the first and second housings 11 and 21 or the display device 22, and signals are effectively transmitted or received by the antenna.

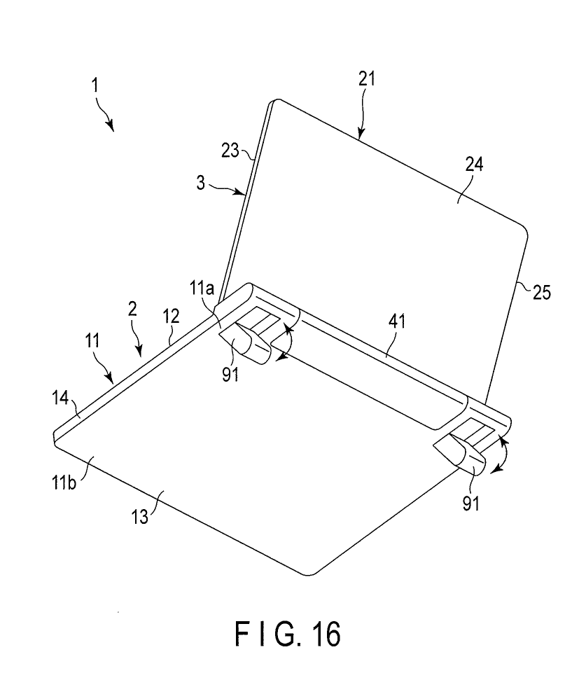

FIG. 16 shows a sixth modification of the electronic apparatus 1. As shown in FIG. 16, in this modification, movable portions 91 are provided in the first end portion 11a of the first housing 11. Similarly to the third housing 31 according to the above-described embodiment, the movable portions 91 are rotated so as to protrude from the opposite side of the operation surface 12 when the second housing 21 is rotated in the direction away from the operation surface 12. As shown in FIG. 16, the movable portions 91 may be provided so as to correspond to a portion of the first housing 11. As shown in FIG. 1, when the width of the movable portion 31 is substantially equal to that of the first and second housings 11 and 21, the electronic apparatus 1 is stably supported by the movable portions 91.

The first to sixth modifications can be applied to the following second and third embodiments.

### Second Embodiment

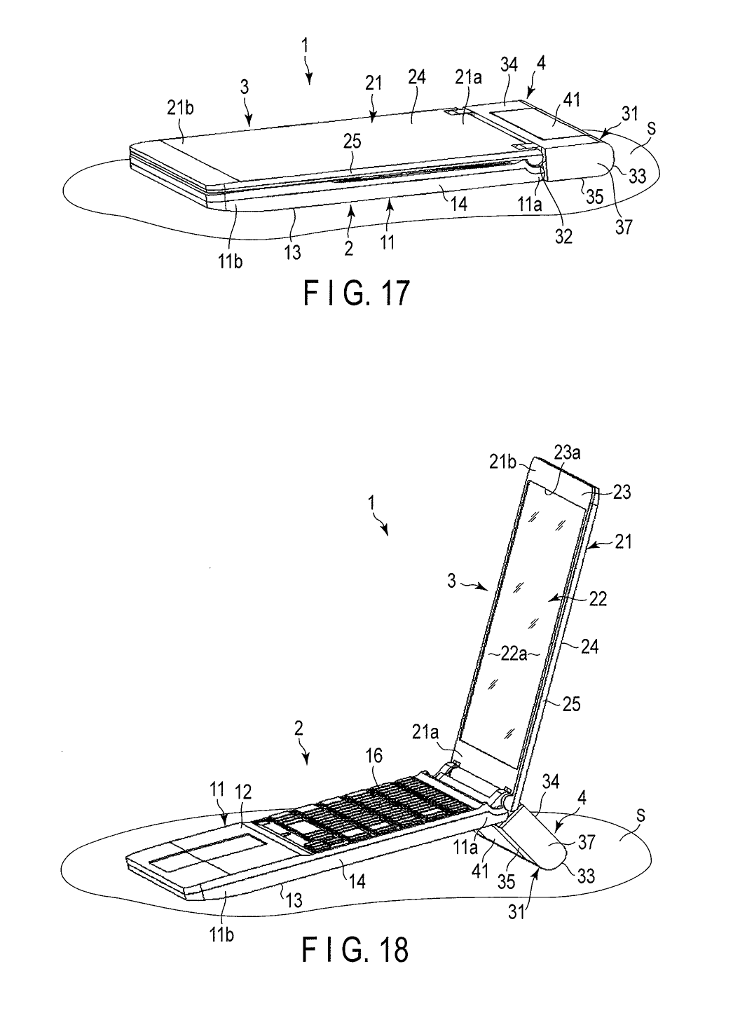

Next, an electronic apparatus 1 according to the second embodiment will be described with reference to FIGS. 17 and 18. In the second embodiment, components having the same or similar functions as those in the first embodiment are denoted by the same reference numerals and a description thereof will not be repeated. Structures other than the following structures are the same as those in the first embodiment.

The electronic apparatus 1 according to this embodiment is, for example, a mobile phone. As shown in FIGS. 17 and 18, similarly to the first embodiment, the electronic apparatus 1 includes a first housing 11, a second housing 21, a third housing 31 (movable portion), and hinges 5 and 6.

### Third Embodiment

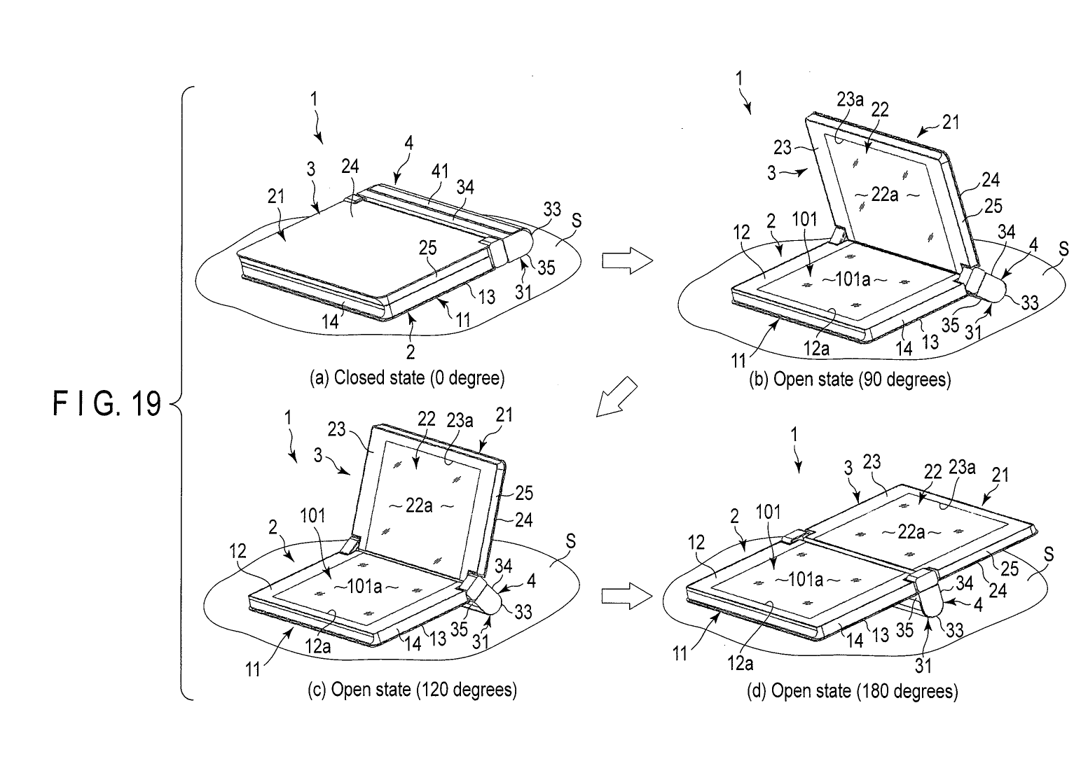

Next, an electronic apparatus 1 according to the third embodiment will be described with reference to FIG. 19. In the third embodiment, components having the same or similar functions as those in the first embodiment are denoted by the same reference numerals and a description thereof will not be repeated. Structures other than the following structures are the same as those in the first embodiment.

As shown in FIG. 19, the electronic apparatus 1 includes a first housing 11, a second housing 21, a third housing 31 (movable portion), and hinges 5 and 6. The first housing 11 has a display device 101 provided therein. The display device 101 includes a display screen 101a. The first housing 11 includes an opening portion 12a through which the display screen 101a is exposed. The display screen 101 is provided with, for example, a touch panel and can receive various kinds of inputs. The display screen 101 is an example of the “input portion” (input receiving portion). Similarly, a display screen 22a of a display device 22 provided in the second housing 21 is provided with, for example, a touch panel and can receive various kinds of inputs.

The electronic apparatus 1 according to this embodiment can be used as, for example, an electronic book reader. The electronic apparatus 1 may be stood longitudinally and may be used with the first and second housings 11 and 21 open like a book.

According to the first to third embodiments, it is possible to provide an electronic apparatus that has a small thickness and can be inclined in use.

The embodiment is not limited to the above-described embodiments, but the components of the above-described embodiments may be changed without departing from the scope and spirit of the invention. In addition, a plurality of components according to the above-described embodiments may be appropriately combined with each other to form various structures. For example, some of the components according to the above-described embodiments may be removed. Components according to different embodiments may be appropriately combined with each other.

For example, the structure of the hinges 5 and 6 is not limited to the biaxial hinge mechanism 51, but the hinges 5 and 6 may have other structures. The electronic component and the battery 41 may not be provided in the movable portion. The mechanism that rotates the third housing 31 (movable portion) in operative association with the rotation of the second housing 21 does not need to be provided at the left and right ends of the electronic apparatus 1, but may be provided only at one of the left and right ends of the electronic apparatus 1. In addition, for example, an antiskid member (for example, a rubber member) may be attached to a portion of the third housing 31 (movable portion) that comes into contact with the desk surface S or a portion of the first housing 11.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic apparatus comprising:
a first housing comprising an operation surface;
a second housing comprising a display device;
a third housing adjacent to a first end of the first housing; and
a hinge comprising:
a first hinge attaching the first housing to the third housing;
a second hinge attaching the second housing to the third housing; and
an interlock between the first hinge and the second hinge, the interlock configured to rotate the third housing in synchronization with the second housing sufficient to cause the third housing to protrude on a side opposite to the operation surface when the second housing is rotated in a direction away from the operation surface.

2. The electronic apparatus of claim 1, wherein:
the first housing comprises a second end opposite to the first end,
the first end is configured to be higher than the second end when the third housing protrudes on the side opposite to the operation surface, and
the second end and the third housing support the first housing.

3. The electronic apparatus of claim 2, wherein, when the third housing protrudes on the side opposite to the operation surface:
the first housing is inclined downward in a first direction from the first end to the second end,
the third housing is inclined downward in a second direction opposite to the first direction, and
the second end and the third housing support the first housing in different directions, respectively.

4. The electronic apparatus of claim 1, wherein the third housing comprises an electronic component.

5. The electronic apparatus of claim 1, further comprising:
a circuit board in the first housing or the second housing; and
a battery in the third housing, the battery being heavier than the circuit board.

6. The electronic apparatus of claim 1, wherein:
the third housing does not overlap the first housing and the second housing when the first housing and the second housing overlap each other, and
the third housing is thicker than the first housing and comprises a connector exposed to an area outside the housing.

7. The electronic apparatus of claim 1, wherein:
the third housing has a thickness substantially equal to a total thickness of the first housing and the second housing, and
a surface of the third housing and a surface of the second housing are substantially on the same plane when the first housing and the second housing overlap each other.

8. The electronic apparatus of claim 1, wherein:
the third housing is substantially parallel to the first housing when the first housing and the second housing overlap each other, and
the third housing is inclined with respect to the first housing when the second housing is rotated in a direction away from the operation surface.

9. The electronic apparatus of claim 1, wherein:
a degree of rotation of the second housing is equal to the sum of a degree of rotation of the first hinge and a degree of rotation of the second hinge,
a degree of rotation of the third housing is equal to the degree of rotation of the first hinge, and
a rotational angle of the third housing is smaller than a rotational angle of the second housing.

10. An electronic apparatus comprising:
a first housing comprising an operation surface;
a second housing;
a hinge attaching the second housing to the first housing; and
a movable portion attached to an end of the first housing by the hinge and configured to be rotated toward an opposite side to the operation surface in synchronization with rotation of the second housing.
